(19) United States
(12) Patent Application Publication
(10) Pub. No.: US 2016/0045886 A1
(43) Pub. Date: Feb. 18, 2016

(54) DEVICE FOR PROTECTING AN ELECTRODE SEAL IN A REACTOR FOR THE DEPOSITION OF POLYCRYSTALLINE SILICON

(71) Applicant: WACKER CHEMIE AG, München (DE)

(72) Inventors: Heinz KRAUS, Zeilarn (DE); Andreas HEGEN, Marktl (DE); Christian KUTZA, Burghausen (DE)

(21) Appl. No.: 14/778,815

(22) PCT Filed: Feb. 26, 2014
(86) PCT No.: PCT/EP2014/053736

§ 371 Date: Sep. 21, 2015

(30) Foreign Application Priority Data
Mar. 20, 2013 (DE) 10 2013 204 926.9

(51) Int. Cl. B01J 19/00; C23C 16/24; C01B 33/035

(52) U.S. Cl. CPC B01J 19/0073; C01B 33/035; C23C 16/24; B01J 2219/0807

(57) ABSTRACT

Electrode support seals in a Siemens reactor for the deposition of polycrystalline silicon are protected against thermal stress and degradation, and shorting by falling fragments is prevented by shielding having a high resistivity and also a high thermal conductivity.

### CROSS REFERENCE TO RELATED APPLICATIONS

This application is the U.S. National Phase of PCT Appln. No. PCT/EP2014/053736 filed Feb. 26, 2014, which claims priority to German Application No. 10 2013 204 926.9 filed Mar. 20, 2013, the disclosures of which are incorporated in their entirety by reference herein.

### BACKGROUND OF THE INVENTION

1. Field of the Invention

The invention relates to a device for protecting an electrode seal in a reactor for the deposition of polycrystalline silicon.

2. Description of the Related Art

Highly pure silicon is generally produced by means of the Siemens method. In this case, a reaction gas containing hydrogen and one or more silicon-containing components is introduced into the reactor comprising the support bodies, which are heated by direct current flow and on which Si is deposited in solid form. As silicon-containing compounds, silane (SiH₄), monochlorsilane (SiH₃Cl), dichlorsilane (SiH₂Cl₂), trichlorsilane (SiHCl₃), tetrachlorsilane (SiCl₄) or mixtures thereof are preferably used.

Each support body usually consists of two thin filament rods and a bridge, which generally connects neighboring rods at their free ends. Most often, the filament rods are made of monocrystalline or polycrystalline silicon, and less commonly metals or alloys or carbon are used. The filament rods are inserted perpendicularly into electrodes located at the reactor bottom, by means of which the connection to the electrode holder and electricity supply is established. Highly pure polysilicon is deposited on the heated filament rods and the horizontal bridge, so that their diameter increases with time. After the desired diameter is reached, the process is ended.

The silicon rods are held in the CVD reactor by special electrodes, which generally consist of graphite. In each case, two filament rods with different voltage poling on the electrode holders are connected at the other thin rod end by a bridge to form a closed circuit. Electrical energy for heating the thin rods is supplied via the electrodes and their electrode holders. The diameter of the thin rods thereby increases. At the same time, the electrode grows, starting at its tip, into the rod base of the silicon rods. After a desired setpoint diameter of the silicon rods is reached, the deposition process is ended and the silicon rods are cooled and extracted.

In this case, particular importance is attached to the protection of the electrode holder fed through the base plate. To this end, the use of electrode sealing protection bodies has been proposed, the arrangement and the shape of the electrode sealing protection bodies and the material used being important in particular.

Between the electrode holder head extending into the deposition system and the base plate, there is an annular body. The latter has two functions: sealing of the feed-through of the electrode holder and electrical insulation of the electrode holder from the base plate.

Owing to the high gas space temperature in the CVD reactor, thermal protection of the sealing body is necessary. An insufficient thermal protection effect entails premature wear of the sealing bodies by burning of the sealing bodies, thermally induced flow of the sealing body, leaking of the reactor, a minimum distance between the electrode holder and the base plate being fallen below, and a ground fault of the charred sealing bodies. A ground fault or leaks lead to failure of the deposition system and therefore termination of the deposition process. This causes a reduced yield and higher costs.

Protective bodies have therefore been proposed in order to protect the seals.

From US 20110305604 A1, it is known to shield the seals of the electrodes against thermal stress by means of protective rings made of quartz. The reactor bottom has a special configuration. The reactor bottom comprises a first region and a second region. The first region is formed by a plate facing toward the interior of the reactor and an intermediate plate, which carries the nozzles. The second region of the reactor bottom is formed by the intermediate plate and a base plate, which carries the supply connections for the filaments. The cooling water is fed into the first region formed in this way, so as to cool the reactor bottom. The filaments themselves are seated in a graphite adapter. This graphite adapter engages in a graphite clamping ring, which itself cooperates with the plate by means of a quartz ring. The cooling water connections for the filaments may be configured in the form of quick-fit couplings.

WO 2011116990 A1 describes an electrode holder having a quartz cover ring. The process chamber unit consists of a contact and clamping unit, a base element, a quartz cover disk and a quartz cover ring. The contact and clamping unit consists of a plurality of contact elements, which can be moved relative to one another and form a reception space for a thin silicon rod. The contact and clamping unit can be introduced into a corresponding reception space of the base element, the reception space for the thin silicon rod becoming narrower during the introduction into the base element, and this rod thereby being reliably clamped and electrically contacted. The base element also has a lower compartment for receiving a contact tip of the feed-through unit. The quartz cover disk has central openings for feeding through the contact tip of the feed-through unit. The quartz cover ring is dimensioned in such a way that it can at least partially radially enclose a feed-through unit region lying inside a process chamber of a CVD reactor.

Since quartz has a low thermal conductivity, however, under the deposition conditions these components become so hot that a thin silicon layer grows at high temperature on their surface. Under these conditions, the silicon layer becomes electrically conductive, which leads to a ground fault.

WO 2011092276 A1 describes an electrode holder in which the sealing element between the electrode holder and the base plate is protected against thermal influences by a ceramic ring extending around it. A plurality of electrodes are fastened in a bottom of the reactor. The electrodes carry filament rods, which are seated in an electrode body and via which the current supply to the electrodes, or filament rods, takes place. The electrode body itself is mechanically prestressed in the direction of the upper side of the bottom of the reactor by a plurality of resilient elements. A sealing ring extending radially around is fitted between the upper side of the bottom of the reactor and a ring of the electrode body, which is parallel to the upper side of the bottom. The sealing element itself is shielded by a ceramic ring in the region between the upper side of the bottom of the reactor and the electrode body ring parallel thereto.

US 20130011581 A1 discloses a device for protecting electrode holders in CVD reactors, comprising an electrode, suitable for receiving a filament rod, on an electrode holder made of an electrically conductive material, which is applied in a recess of a base plate, an intermediate space between the electrode holder and the base plate being sealed by a sealing material and the sealing material being protected by a protective body, constructed in one or more pieces, arranged annularly around the electrodes, the protective body increasing in its height at least in sections in the direction of the electrode holder. Geometrical bodies are provided in a concentric arrangement around the electrode holder, their height decreasing with an increasing distance from the electrode holder. The body may also be in one piece. It is used for thermal protection of the sealing and insulation body of the electrode holder and for flow modification at the rod base of the deposited polysilicon rods, in order to positively influence the incidence of overturning.

In the devices according to WO 2011092276 A1 and US 20130011581 A1, a ground fault can occur despite thermal protection of the seal between the electrode holder and the base plate. Short circuits lead to abrupt process termination by failure of the current supply for heating the rods. The rods cannot be brought to the intended final diameter. With thinner rods, the system capacity becomes less, which entails significant costs.

### SUMMARY OF THE INVENTION

The previously discussed problems gave rise to the object of the invention, namely to permit effective protection against ground faults and thermal shielding of the sealing body. These and other objects are achieved by a device for protecting an electrode seal in a reactor for the deposition of polycrystalline silicon, wherein a sealing body (2) is arranged in an intermediate space between an electrode holder (1) of the electrode and a base plate (3) of the reactor, and wherein a protective ring (4) which extends radially around the electrode holder (1) and the sealing body (2) and touches the base plate is provided, or wherein a cover (6) which extends radially around the electrode holder (1) and the sealing body (2) and touches the electrode holder (1) is provided, with the condition that if apart from the protective ring (4) no further protective bodies extending radially around the electrode holder (1) and the sealing body (2) or touching the electrode holder are provided, the one-piece or multi-piece protective ring (4) laterally touches the electrode holder (1) and consists of an electrically insulating material having an electrical resistivity at room temperature of more than 10⁹ Ωcm, preferably more than 10¹¹ Ωcm, and also has a thermal conductivity at room temperature of more than 10 W/mK, preferably more than 20 W/mK.

### BRIEF DESCRIPTION OF THE DRAWINGS

FIG. 1 shows a device according to the prior art with a protective ring extending around and not touching the electrode holder.

FIG. 2 shows one embodiment of the invention with a protective ring and a cover disk.

FIG. 3a shows an embodiment of the invention with a cover which is L-shaped in radial cross section and without a protective ring.

FIG. 3b shows another embodiment of the invention with a cover which is L-shaped in radial cross section and with a protective ring.

FIG. 4 shows another embodiment of the invention with a protective ring, which laterally touches the electrode holder.

FIG. 5 shows another embodiment of the invention with a protective ring and a cover cap.

FIG. 6 shows another embodiment of the invention with a protective ring and ring segments.

FIG. 7 shows another embodiment of the invention with a protective ring and a cover disk bearing thereon.

FIG. 8 shows another embodiment of the invention with a vertically displaceable cover and a protective ring.

### DETAILED DESCRIPTION OF THE PREFERRED EMBODIMENTS

In the device according to the invention and the embodiments explained below, the protective rings/covers provided are configured in such a way that at least the part of the base plate between the electrode holder, or the sealing body, and the protective body/cover is protected from above. This prevents silicon splinters from falling between the protective ring and the electrode holder and being able to bridge the electrical insulation of the electrode holder from the base plate. This has been a cause of the ground faults observed in the prior art.

Preferably, the device provides a protective ring (4) in conjunction with a cover disk (5), the cover disk bears on the electrode holder (1), there is no contact between the protective ring (4) and the cover disk (5), the cover disk (5) protects the protective ring (4) from above, and there is a distance of at least 5 mm between the protective ring (4) and the cover disk (5).

Preferably, in the device, a protective ring (4) is provided in conjunction with a cover disk (5), the cover disk (5) bears on the protective ring (4), the cover disk (5) does not touch the electrode holder (1), and either the cover disk (5) or the protective ring (4) consists of an electrically insulating material having an electrical resistivity at room temperature of more than 10⁹ Ωcm, preferably more than 10¹¹ Ωcm, and this also has a thermal conductivity at room temperature of more than 10 W/mK, preferably more than 20 W/mK.

Preferably, the device does not have a protective ring (4), but only has a cover (6), the cover (6) touching both the base plate (3) and the electrode holder (1), the cover (6) touches the electrode holder both laterally and from above, and the cover (6) consists of an electrically insulating material having an electrical resistivity at room temperature of more than 10⁹ Ωcm, preferably more than 10¹¹ Ωcm, which also has a thermal conductivity at room temperature of more than 10 W/mK, preferably more than 20 W/mK. Preferably, the cover is L-shaped in radial cross section.

Preferably, the device comprises both a protective ring (4) and a cover (6), the cover (6) touches the electrode holder (1) laterally and from above, there is no contact between the cover (6) and the base plate (3), and a protective ring (4) laterally offset relative to the cover (6) is provided, which touches the base plate and closes a lateral gap between the cover (6) and the base plate (3). Preferably, the cover is L-shaped in radial cross section.

It is likewise preferred for the cover (6) to be mobile in the vertical direction and for the protective ring (4) and the cover (6) to consist of an electrically insulating material having an electrical resistivity of more than 10⁹ Ωcm at room temperature, preferably more than 10¹¹ Ωcm at room temperature. The cover (6) has a thermal conductivity at room temperature of more than 10 W/mK, preferably more than 20 W/mK.

Preferably, the device comprises a protective ring (4) and a cover cap (7), the cover cap (7) touching the electrode holder (1) laterally and/or above (above is not represented in the figure), but does not touch the base plate (3), and the cover cap (7) is arranged above the protective ring (4) but does not touch it.

Preferably, the device comprises ring segments (8) extending radially around the protective ring (4) and the electrode holder (1), the protective ring (4) is separated further from the electrode holder (1) thus the ring segments (8) and both the protective ring (4) and the ring segments (8) consist of an electrically insulating material having an electrical resistivity at room temperature of more than 10⁹ Ωcm, preferably more than 10¹¹ Ωcm at room temperature, which also has a thermal conductivity at room temperature of more than 1 W/mK.

The invention also relates to a method for producing polycrystalline silicon, comprising introduction of a reaction gas containing a silicon-containing component and hydrogen into a CVD reactor containing at least one filament rod, which is located on one of the devices mentioned above and is supplied with current by means of the electrode, and which is thereby heated by direct current flow to a temperature at which silicon is deposited on the filament rod.

The device according to the invention and embodiments thereof which are described in detail below provide different forms of electrode covers, which are manufactured in such a way that the sealing body is shielded from the heat flow and heat radiation. With a high feed throughput and large rod diameter, the sealing bodies become particularly thermally stressed. Under these conditions, particularly great importance is attached to the thermal protection of the electrode cover.

The electrode covers therefore have two functions:

encapsulation of the electrode holder in the region of the sealing body from the base plate of the reactor space, so that no bridging of the sealing body from the electrode holder to the base plate by silicon splinters is possible;

reducing the thermal stress on the sealing body by improved thermal protection.

Several embodiments of electrode covers are possible, namely protective rings, cover disks, covers which are L-shaped in radial cross section, cover caps and ring segments. They may have a one-piece or multi-piece structure.

Great demands are placed on their material properties. At the high gas space temperatures, they must be stable both thermally and chemically in a hydrogen silane/HCl/H₂ atmosphere.

Depending on the embodiment, distinction is also necessary between electrical conductors and nonconductors, with low and high thermal conductivity, as will be shown in the detailed description of the preferred embodiments.

In order to increase the thermal dissipation from protective bodies to the cooled electrode holder, the cover cap, or a protective ring bearing on the electrode holder, may be firmly connected releasably to the electrode holder, for example by a screw connection. In this case, the electrode holder has an external screw thread, the cover cap or the protective ring has an internal screw thread.

The preferred embodiments will be explained below.

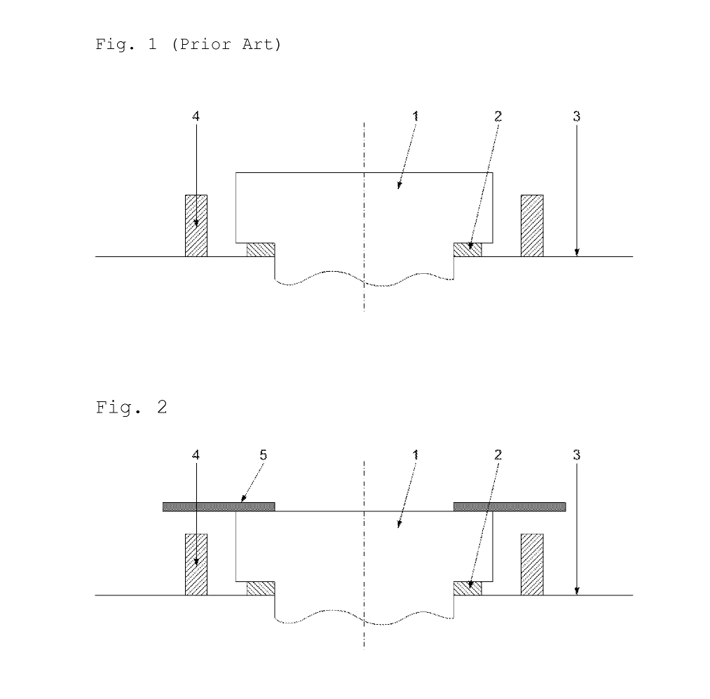

Reference will also be made to FIGS. 1-7.

FIG. 1 shows an embodiment according to the prior art. An electrode holder 1 is applied on the base plate 3 of a reactor. A sealing body 2 is arranged between the base plate 3 and the head of the electrode holder 1. A protective ring 4 extending around is provided in order to protect the sealing body 2.

### First Preferred Embodiment

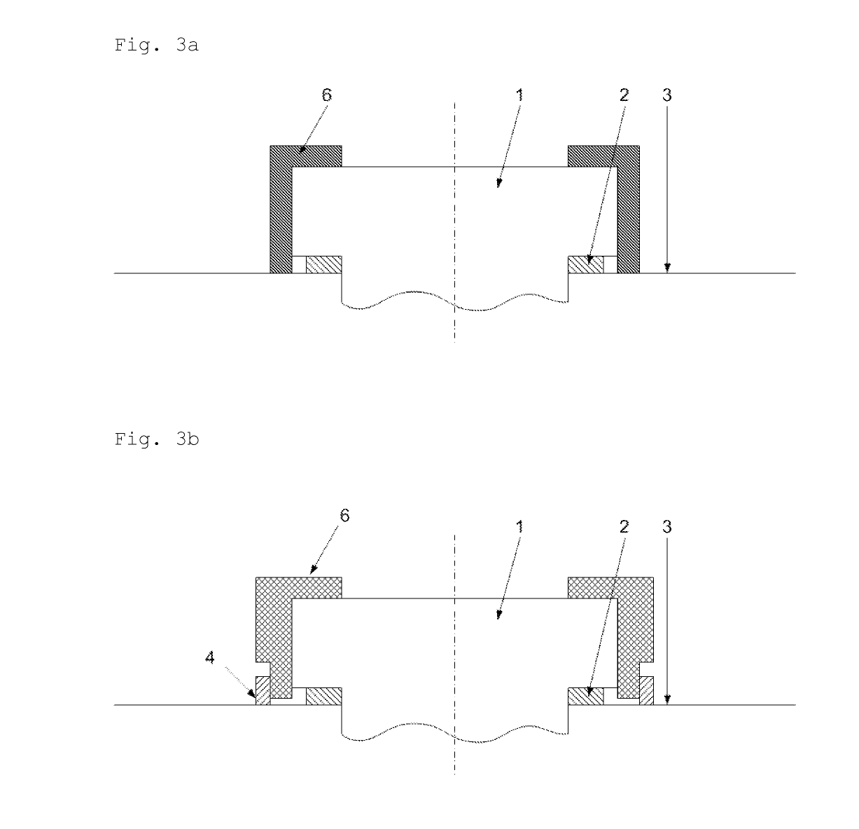

FIG. 2 schematically shows a first preferred embodiment.

At least one protective ring 4 is provided on the base plate 3, in combination with a cover disk 5 on the electrode holder 1.

The protective ring 4 encloses the sealing body 2 by extending radially around.

The cover disk 5 and the protective ring 4 are separated by a gap extending around. The gap distance should be dimensioned to be at least large enough so that no sparkover takes place from the cover disk to the protective ring at the maximum applied voltage. A gap distance of more than 5 mm is preferred. In this way, neither electrical contact nor electrical sparkover to the base plate 3 is possible.

The protective ring 4 is at a distance from the electrode holder 1. The gap distance should be dimensioned to be at least large enough so that no sparkover takes place from the protective ring to the electrode holder at the maximum applied voltage. A gap distance of more than 5 mm is preferred.

Since the protective ring 4 has no contact with the electrified electrode holder 1, nor with the cover disk 5, the two parts may consist either of an electrically conductive material or of an electrically nonconductive material.

There is likewise no restriction for the thermal conductivity of the materials of the two bodies. The growth of a thin silicizing layer is allowed.

Suitable materials are therefore: quartz, preferably translucent quartz, graphite, preferably ultrapure graphite, SiC, graphite with silicon or SiC coating, Si₃N₄, AlN, Al₂O₃, other stable ceramic materials, stable metals, for example Ag or Au.

The protective ring 4 extending radially around shields the sealing body 2 from the hot gas flow. The cover disk 5 on the electrode holder 1 prevents a silicon splinter from falling onto the electrode holder 1 in a direct path and causing a ground fault. By virtue of the gap extending radially around, electrical contact between the protective ring 4 and the cover disk 5 is prevented.

The cover disk 5 may consist of an electrically conductive material or of an electrically nonconductive material. Suitable materials are therefore, for example: quartz, preferably translucent quartz, graphite, preferably ultrapure graphite, SiC, graphite with silicon or SiC coating, Si₃N₄, AlN, Al₂O₃, other stable ceramic materials, stable metals, for example Ag or Au.

Possible silicizing (growth of a thin silicon layer during the deposition process) has no negative influence. Since there are no restrictions in relation to electrical and thermal conductivity, economical materials may preferably be used (for example: graphite, metals). The only criterion is chemical and thermal stability.

Furthermore, by virtue of the annular gap, good gas exchange is possible in flushing processes. The protective bodies have no contact with the sealing body, so that they cannot transmit the heat by conduction.

### Second Preferred Embodiment

FIG. 3a shows a second preferred embodiment.

Here, at least one cover 6 is provided, which touches the electrode holder 1 and the base plate 3.

The cover 6 encloses the sealing body 2 by extending radially around.

The cover 6 must be made of an electrically insulating material with very good thermal conductivity. Silicizing of the cover 6 is therefore not possible.

For this, silicon nitride and aluminum nitride may be envisioned, or other ceramic materials with a high thermal conductivity at room temperature of more than 10 W/mK, preferably more than 50 W/mK at room temperature, most preferably more than 150 W/mK at room temperature; and an electrical resistivity at room temperature of more than 10⁹ Ωcm, preferably more than 10¹¹ Ωcm at room temperature.

In order to increase the thermal dissipation from the cover 6, the cover 6 may preferably be connected firmly to the cooled electrode holder 1, for example by a screw thread (not represented in the figure) at the circumference of the electrode holder 1.

The cover 6 extending radially around, made of an electrical insulator with the described properties, combines the function of splinter protection and thermal protection of the sealing body 2.

The cover 6 must touch the cooled base plate 3 and the cooled electrode holder 1.

Owing to the high thermal conductivity, the surface temperature of the cover 6 is so low by dissipation of the heat to the cooled electrode holder 1 and to the cooled base plate 3 that an electrically conductive silicon layer cannot grow.

Owing to the high electrical resistivity, no ground faults occur via the cover 6.

Owing to the full encapsulation, falling silicon splinters cannot initiate ground faults since no contact with the electrode holder 1 and the base plate 3 is possible.

The cover 6 furthermore shields the sealing body 2 from the hot gas flow.

The cover 6 has no contact with the sealing body 2, so that heat cannot be transmitted by conduction.

For this variant, material properties such as high thermal conductivity of more than 10 W/mK, preferably more than 50 W/mK, most preferably more than 150 W/mK, high electrical resistivity (insulator) of more than 10⁹ Ωcm, and chemical and thermal stability and high purity are necessary. Suitable materials are: Si₃N₄ (silicon nitride), AlN (aluminum nitride) or other ceramic materials which fulfil said criteria.

FIG. 3b shows a modification of the embodiment represented in FIG. 3a.

A preferred refinement consists of a combination of the cover 6 with a protective ring 4.

The cover 6 can be moved in its lateral side with the electrode holder 1 vertically with respect to the base plate 3.

The combination consists of a lower protective ring 4, which bears on the base plate, and the cover 6, which bears on the electrode holder and is preferably firmly connected thereto, for example in the form of a screw connection.

This ensures that the cover 6 can compensate for manufacturing tolerances of the electrode holder 1 and seating behavior of the sealing body 2.

The cover 6 and the protective ring 4 are dimensioned in such a way that the protective ring 4 and the cover 6 engage in one another and ensure a constant overlap. In this way, even in the event of manufacturing tolerances of the electrode holder 1 and in the seating of the sealing body 2, this always ensures that the cover 6 bears on the electrode holder 1 and there is always an overlap with the protective ring 4 on the lateral side of the cover 6.

An overlap of the lateral side of the cover 6 with the protective ring 4 ensures full separation of the electrode holder 1 from the reactor space in the region of the sealing body 2.

For better ventilation of the enclosed space around the electrode holder 1 during flushing steps in order to inert the deposition reactor, the cover 6 and/or the protective ring 4 may contain small bores (not represented in the figure) on the circumference and/or on the upper side.

For this variant, material properties of the cover 6 and the protective ring 4 such as high thermal conductivity of more than 10 W/mK at room temperature, preferably more than 50 W/mK at room temperature, most preferably more than 150 W/mK at room temperature, high electrical resistivity (insulator) at room temperature of more than 10⁹ Ωcm, preferably more than 10¹¹Ωcm at room temperature, and chemical and thermal stability and high purity are necessary. Suitable materials are: Si₃N₄ (silicon nitride), AlN (aluminum nitride) or other ceramic materials which fulfil said criteria.

### Third Preferred Embodiment

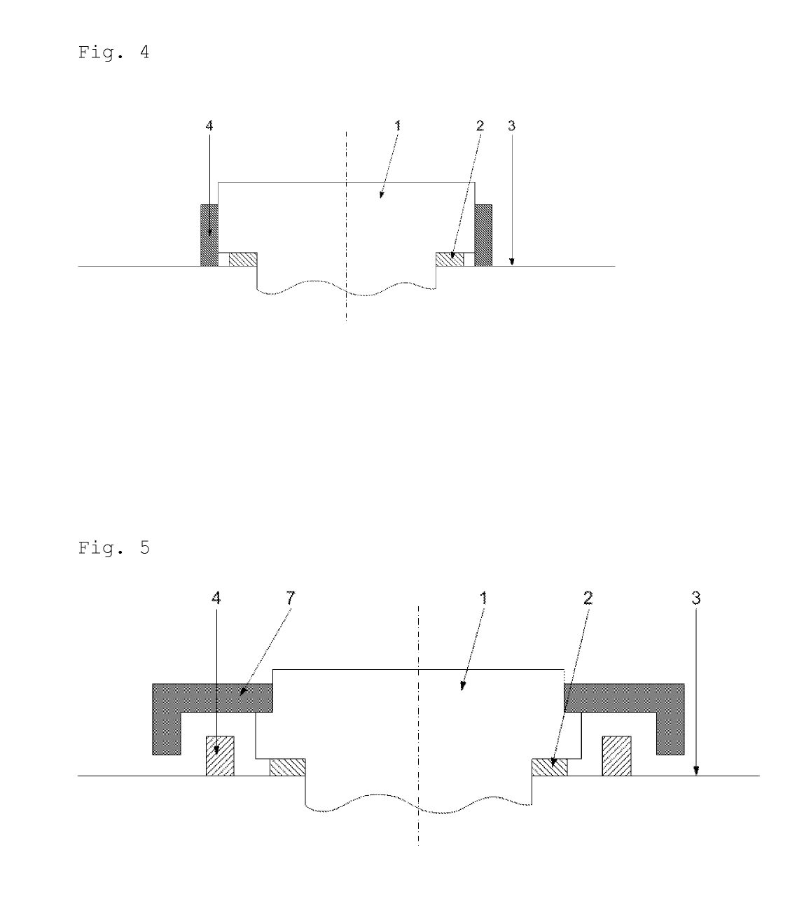

FIG. 4 shows the third preferred embodiment.

This embodiment represents a protective ring 4 made of an electrically nonconductive material.

The protective ring 4 must be made of an electrically insulating material with very good thermal conductivity. For this, silicon nitride and aluminum nitride may be envisioned, or other ceramic materials with a high thermal conductivity (at room temperature) of more than 10 W/mK, preferably more than 50 W/mK, most preferably more than 150 W/mK; and an electrical resistivity (at room temperature) of more than 10⁹ Ωcm, preferably more than 10¹¹ Ωcm.

The protective ring 4 encloses the sealing body 2 and the electrode holder 1 by extending radially around, and establishes contact between the cooled electrode holder 1 and the cooled base plate 3 for the purpose of thermal dissipation.

The protective ring 4 may consist of one piece or be composed of any desired number of component pieces to form a ring.

In the case of a one-piece protective ring 4, the protective ring 4 may be releasably connected firmly to the electrode holder 1, for example by a screw connection (not represented in the figure).

In this way, the heat transfer from the protective ring 4 to the cooled electrode holder 1 is increased, which leads to lower surface temperatures on the protective ring 4. This has advantages in relation to long lifetime (less thermal and chemical corrosion) and a lower surface temperature of the protective ring 4.

Around the protective ring 4, an outer protective ring (not represented) of quartz, ceramic or a stable metal (for example: silver, stainless steel, gold) may be arranged at a distance. The optional protective ring additionally shields the inner protective ring 4 from thermal radiation of the silicon rods and hot gas flow. In this way, the inner protective ring 4 is less thermally stressed.

The protective ring 4 which extends around radially and consists of an electrical insulator with the described properties combines the function of splinter protection and thermal protection of the sealing body 2.

The protective ring 4 must touch the cooled base plate 3 and the cooled electrode holder 1.

Owing to the high thermal conductivity, the surface temperature of the protective ring 4 is so low by dissipation of the heat to the cooled electrode holder 1 and to the cooled base plate 3 that an electrically conductive silicon layer cannot grow.

Owing to the high electrical resistivity, no ground faults occur via the protective ring 4.

Owing to the full encapsulation, falling silicon splinters cannot initiate ground faults since no contact of the splinters with the electrode holder 1 and the base plate 3 is possible.

The protective ring 4 furthermore shields the sealing body 2 from the hot gas flow.

The protective ring 4 has no contact with the sealing body 2 so that the heat cannot be transmitted by conduction.

By virtue of the optional outer protective ring, the effect of the thermal shielding is further enhanced.

### Fourth Preferred Embodiment

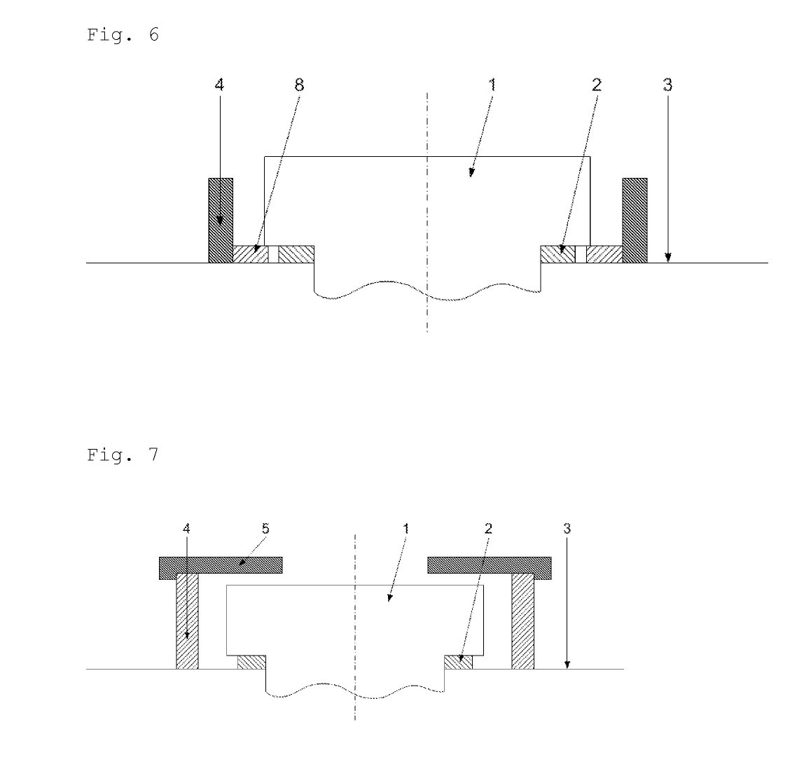

FIG. 5 shows the fourth preferred embodiment.

This embodiment provides at least one protective ring 4 on the base plate 3 in combination with a cover cap 7 on the electrode holder 1.

The protective ring 4 encloses the sealing body 2 by extending radially around.

The cover cap 7 and the protective ring 4 overlap in such a way that there is no contact between the cover cap 7 and the protective ring 4.

Furthermore, the cover cap 7 and the protective ring 4 overlap in the vertical direction in such a way that no passage to the sealing body 2 in a straight line is possible.

In this way, silicon splinters cannot reach the sealing body 2.

Since the protective ring 4 has no contact with the electrified electrode holder 1, nor with the cover cap 7, the two parts may consist either of an electrically conductive material or of an electrically nonconductive material.

There is likewise no restriction for the thermal conductivity of the materials of the two bodies. The growth of a thin silicizing layer is allowed.

Suitable materials are therefore: quartz, preferably translucent quartz, graphite, preferably ultrapure graphite, SiC, graphite with silicon or SiC coating, Si₃N₄, AlN, Al₂O₃, other stable ceramic materials, stable metals, for example Ag or Au.

For better thermal dissipation from the cover cap 7 to the cooled electrode holder 1, the cover cap 7 may be firmly connected to the electrode holder 1, for example by a screw connection.

The protective ring 4 extending radially around shields the sealing body 2 from the hot gas flow.

The cover cap 7 on the electrode holder 1 with an edge drawn down in the direction of the base plate 3 prevents a silicon splinter from falling onto the electrode holder 1 and the sealing body 2 in a direct or indirect path, and therefore causing a ground fault, owing to the vertical overlap of the cover cap 7 and the protective ring 4.

Owing to the vertical overlap of the cover cap 7 and the protective ring 4 and a sufficiently large distance of 3-40 mm, preferably 5-10 mm, between the cover cap 7 and the protective ring 4, electrical contact of the silicized parts can be prevented.

The distance between the cover cap 7 and the base plate 3 must be dimensioned to be large enough that no sparkover from the cover cap to the base plate occurs at the maximum applied voltage. The gap distance is preferably more than 5 mm.

Furthermore, owing to the vertical overlap, good gas exchange inside the cover cap 7 in the region of the electrode holder 1 is possible during flushing processes.

The cover cap 7 and the protective ring 4 have no contact with the sealing body 2, so that they cannot transmit heat by conduction.

### Fifth Preferred Embodiment

FIG. 6 shows a fifth preferred embodiment. This embodiment provides at least one protective ring 4 on the base plate 3 in combination with ring segments 8, which are inserted between the electrode holder 1 and the base plate 3 and cover the base plate 3 at least between the electrode holder and the protective ring 4.

The ring segments 8 may be assembled to form a complete ring.

The ring segments 8 are inserted between the electrode holder 1 and the base plate 3 in the direction of the sealing body 2, the ring segments 8 being dimensioned in such a way that there is a distance from the ring segment 8 to the sealing body 2 of 0-20 mm, preferably 2-5 mm, after the insertion between the electrode holder 1 and the base plate 3.

Instead of ring segments 8, it is also possible to use a complete ring, which is installed between the base plate 3 and the electrode holder 1 during mounting of the electrode holder 1 in the base plate 3.

The protective ring 4 and the ring segments 8 are made of an electrically insulating material with a resistivity of more than 10⁹ Ωcm at room temperature, preferably more than 10¹¹ Ωcm at room temperature, and a thermal conductivity of more than 1 W/mK at room temperature, preferably more than 20 W/mK at room temperature, most preferably more than 150 W/mK at room temperature. Suitable materials are, for example, quartz, preferably translucent quartz, Si₃N₄, AlN, Al₂O₃, or other corresponding ceramic materials.

Owing to the preferred small thickness of the ring segments 8, between 3 and 20 mm, most preferably 3-10 mm, most preferably 3-7 mm, the high thermal conductivity and the large bearing surface on the cooled base plate 3, the radiation received by the ring segments 8 from the rod bases can be dissipated well via the cooled base plate 3.

The surface temperature of the ring segments 8 is therefore so low that no silicizing on their surface is possible under deposition conditions. There is therefore also no electrical conductivity.

The protective ring 4 is preferably at a distance of 5-50 mm, more preferably 5-20 mm, most preferably 5-10 mm, from the electrode holder 1. It is therefore sufficient for the protective ring 4 to remain free of silicizing in the region of between 0 and 5 mm in the direction of the base plate 3.

This is satisfied owing to the good thermal dissipation to the base plate 3 with the indicated thermal conductivity of the protective ring 4.

Owing to the covering of the base plate 3, this combination represents effective splinter protection, since owing to the ring segments 8 no electrical contact of a silicon splinter with the electrode holder 1 and the base plate 3 is possible. At the same time, the sealing body 2, in conjunction with the ring segments 8 and the protective ring 4, is protected better from the hot reactor gas.

The ring segments 8 fully cover the base plate between the protective ring 4 and the electrode holder 1. Owing to the necessary high thermal conductivity of the ring segments 8 and of the protective ring 4, of more than 1 W/mK at room temperature, preferably more than 20 W/mK at room temperature, most preferably more than 150 W/mK at room temperature and the high electrical resistivity (insulator) of more than 10⁹ Ωcm at room temperature, preferably more than 10¹¹ Ωcm at room temperature, the base plate 3 is electrically shielded fully in relation to the electrode holder 1. This constitutes effective splinter protection.

Compared with the prior art, the ring segments 8 lead to additional thermal protection of the sealing body 2 and additional protection against ground faults between the electrode holder 1 and the protective ring 4, caused by silicon splinters.

Furthermore, owing to the high thermal conductivity of the protective ring 4 and of the ring segments 8, absorbed heat (reaction gas and radiation) is released to the cooled base plate 3 so that the surface temperature of the protective ring 4 and ring segments 8 does not become so hot that the ring segments 8 could silicide, or the protective ring 4 and the ring segments 8 could silicide in the region toward the base plate 3.

Another advantage is that, owing to the low surface temperature of the protective ring 4 and ring segments 8, the sealing body 2 is thermally stressed less by radiation.

In addition, the sealing body 2 is fully shielded from the hot reaction gas. The ring segments 8 are dimensioned in such a way that they have no contact with the sealing body 2, so that heat cannot be transmitted by conduction to the sealing body 2.

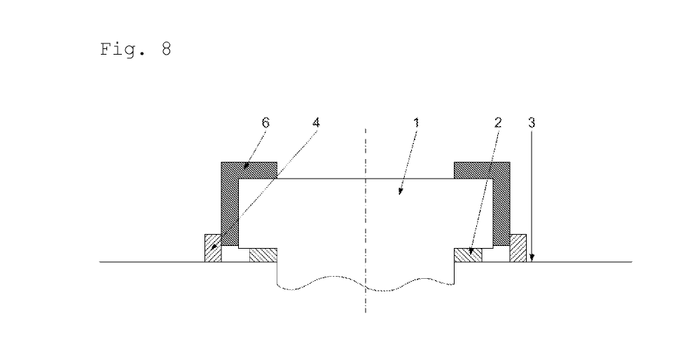

FIG. 7 and FIG. 8 show other possible embodiments.

FIG. 7 shows a protective ring 4 with a disk 5 bearing thereon. In this embodiment, the protective ring 4 and the disk 5 may be made of an electrically conductive or electrically nonconductive material with any thermal conductivity. There must be a distance of at least 5 mm between the disk 5 and the electrode holder 1, and there must likewise be a distance of at least 5 mm between the protective ring 4 and the electrode holder 1.

FIG. 8 shows an embodiment with vertically displaceable protective bodies. A cover 6, made of an electrical nonconductor, extending around and a protective ring 4, made of an electrical nonconductor, extending around are provided.

### EXAMPLES AND COMPARATIVE EXAMPLES

In a Siemens deposition reactor, polycrystalline silicon rods with a diameter of between 160 and 230 mm were deposited. A plurality of embodiments of protective bodies were tested. The parameters of the deposition process were respectively the same in all the tests. The tests differed only by the embodiment of the protective bodies. The deposition temperature in the batch run was between 1000° C. and 1100° C. During the deposition process, a feed consisting of one or more chlorine-containing silane compounds of the formula SiHₙCl₄₋ₙ (with n=0 to 4) and hydrogen as carrier gas was supplied.

### Comparative Example

CVD reactor with a simple protective body for the sealing body, as represented in FIG. 1.

In this embodiment according to the prior art, only a simple ring of translucent quartz for protecting the sealing body was placed at a distance of 10 mm around the electrode holder. Of 100 batches, 20 batches failed owing to ground fault during the deposition. The causes of the failure were Si splinters, which were shed from the silicon rods owing to thermal stresses because of the high feed throughput. These fell between the electrode holder and the quartz ring, where they established an electrically conductive connection between the electrode holder and the base plate. Because of the high thermal stress on the sealing body due to an insufficient protective effect of the quartz ring, the lifetime of the sealing body was limited to 2 months. Owing to the thermal stress due to the hot reaction gas, both the sealing of the base plate and the electrical insulation were not maintained owing to thermal cracking and settling of the sealing body. After this time, elaborate replacement of all the sealing bodies was therefore necessary. Batch failure and repair work led to a significant capacity loss.

### Example 1 (According to the First Preferred Embodiment)

A cover disk of the ultrapure graphite was placed on the electrode holder. In order to protect the sealing body, a ring of translucent quartz was placed at a distance of 10 mm around the electrode holder. The cover disk is dimensioned in such a way that it shields the electrode holder and at least the region of the base plate with the quartz ring from above. Owing to the high gas space temperature, the quartz ring and the cover disk are silicized with a thin silicon layer during the deposition. Between the cover plate and the quartz ring, a gap extending around is dimensioned in such a way that no electrical sparkover from the cover disks to the quartz ring can occur at the applied voltage.

Of 100 batches, 5 batches failed owing to ground fault. Individual silicon splinters reached the electrode holder through the gap extending around, and led to a ground fault between the electrode holder and the base plate. Owing to the additional shielding of the cover disks, the lifetime of the sealing body was increased to 4 months.

### Example 2 (According to the Second Preferred Embodiment)

The electrode holder and the sealing body were protected by applying a cap made of aluminum nitride. In this embodiment, the cap has contact with the electrode holder both above and on the cylindrical part of the electrode holder, and reaches as far as the base plate. Owing to the high thermal conductivity of 180 W/mK (at room temperature), and the dissipation of the absorbed heat by the reaction gas and thermal conduction via the cooled contact surfaces, the surface temperature is so low that no siliciding of the cap surface takes place. Furthermore, the cap material is electrically insulating. Owing to the full encapsulation of the sealing body, a ground fault due to silicon splinters cannot occur. Correspondingly, the ground fault ratio of 100 batches was 0%. Owing to the lower cap temperature, the lifetime of the sealing body was increased to 9 months.

### Example 3 (According to the Third Preferred Embodiment)

The electrode holder and the sealing body were protected by applying a protective ring made of aluminum nitride. The protective ring has contact with the cooled electrode holder and with the cooled base plate. Owing to the high thermal conductivity of 180 W/mK at room temperature, and the dissipation of the absorbed heat by the reaction gas and thermal dissipation via the cooled contact surfaces, the surface temperature is so low that no siliciding of the ring surface takes place. Furthermore, the ring material is electrically insulating. Owing to the full encapsulation of the sealing body, a ground fault due to silicon splinters cannot occur. Correspondingly, the ground fault ratio of 100 batches was 0%. Owing to the lower ring temperature, the lifetime of the sealing body was increased to 9 months.

### Example 4 (According to the Fourth Preferred Embodiment)

The electrode holder and the sealing body were protected by the combination of a protective ring and a cover cap. The protective ring consists of translucent quartz and the cover cap consists of ultrapure graphite. The protective bodies were arranged in such a way that no electrical contact between the two was possible. There was a vertical overlap of the cap edge and the protective ring, so that silicon splinters could not reach the sealing body. Correspondingly, the ground fault ratio was 0%. Owing to the vertical overlap of the cap edge and the protective ring, the sealing body was thermally protected particularly well. The lifetime of the sealing body was increased to 7 months.

### Example 5 (According to the Fifth Preferred Embodiment)

The electrode holder and the sealing body were protected by the combination of ring segments and a protective ring. The ring segments and the protective ring were made of an aluminum nitride ring with a thermal conductivity of 180 W/mK at RT. Owing to the contact with the cooled base plate, the absorbed heat could be dissipated well. Furthermore, the protective body material is electrically insulating. Owing to the full encapsulation of the sealing body, a ground fault due to silicon splinters cannot occur. Correspondingly, the ground fault ratio was 0%. Owing to the lower ring segment temperature, the lifetime of the sealing body was increased to 9 months.

### LIST OF THE REFERENCES USED

1 electrode holder

2 sealing body

3 base plate

4 protective ring

5 cover disk

6 cover

7 cover cap

8 ring segments

1-9. (canceled)

10.-25. (canceled)

26. A device for protecting an electrode seal in a polycrystalline silicon deposition reactor, comprising:
a sealing body positioned in an intermediate space between an electrode holder of the electrode and a base plate of the reactor;
a protective ring which extends radially around the electrode holder and the sealing body and touches the base plate; and
a cover cap which bears on the electrode holder but does not touch the base plate; wherein the cover cap is positioned above the protective ring but does not touch the protective ring.

27. The device of claim 26, wherein the cover cap comprises an edge drawn down in the direction of the base plate such that the cover cap and the protective ring overlap in a vertical direction.

28. The device of claim 26, wherein a distance between the cover cap and the protective ring is from 3 to 40 mm.

29. The device of claim 27, wherein a distance between the cover cap and the protective ring is from 3 to 40 mm.

30. The device of claim 26, wherein a distance between the cover cap and the base plate is more than 5 mm.

31. The device of claim 27, wherein a distance between the cover cap and the base plate is more than 5 mm.

32. The device of claim 28, wherein a distance between the cover cap and the base plate is more than 5 mm.

33. A device for protecting an electrode seal in a polycrystalline silicon deposition reactor, comprising:
a sealing body positioned in an intermediate space between an electrode holder of the electrode and a base plate of the reactor;
a protective ring which extends radially around the electrode holder and the sealing body and touches the base plate; and
a cover which touches the electrode holder laterally and from above, wherein there is no contact between the cover and the base plate, the protective ring is laterally offset relative to the cover, and the protective ring closes a lateral gap between the cover and the base plate.

34. The device of claim 33, wherein the cover is moveable in a vertical direction and the protective ring and the cover comprise of an electrically insulating material having an electrical resistivity of more than 10⁹ Ωcm at room temperature.

35. A device for protecting an electrode seal in a polycrystalline silicon deposition reactor comprising:
a sealing body positioned in an intermediate space between an electrode holder of the electrode and a base plate of the reactor;
a protective ring which extends radially around the electrode holder and the sealing body and touches the base plate; and
a cover which extends radially around the electrode holder and the sealing body and touches the electrode holder and the base plate;
wherein the cover touches the electrode holder both laterally and from above, and the cover comprises an electrically insulating material having an electrical resistivity at room temperature of more than 10⁹ Ωcm and a thermal conductivity at room temperature of more than 10 W/mK.

36. A device for protecting an electrode seal in a polycrystalline silicon deposition reactor comprising:
a sealing body positioned in an intermediate space between an electrode holder of the electrode and a base plate of the reactor;
a protective ring which extends radially around the electrode holder and the sealing body and touches the base plate; and
ring segments extending radially around the protective ring and the electrode holder,
wherein the protective ring is separated further from the electrode holder than the ring segments, and wherein both the protective ring and the ring segments comprise an electrically insulating material having an electrical resistivity at room temperature of more than 10⁹ Ωcm and a thermal conductivity at room temperature of more than 1 W/mK.

37. A method for producing polycrystalline silicon, comprising introducing a reaction gas containing a silicon-containing component and hydrogen into a CVD reactor containing at least one filament rod positioned on a device of claim 26, and supplying current by means of the electrode, thereby heating the filament rod by direct current flow to a temperature at which polycrystalline silicon is deposited on the filament rod, and depositing polycrystalline silicon onto the filament rod.

38. A method for producing polycrystalline silicon, comprising introducing a reaction gas containing a silicon-containing component and hydrogen into a CVD reactor containing at least one filament rod positioned on a device of claim 27, and supplying current by means of the electrode, thereby heating the filament rod by direct current flow to a temperature at which polycrystalline silicon is deposited on the filament rod, and depositing polycrystalline silicon onto the filament rod.

39. A method for producing polycrystalline silicon, comprising introducing a reaction gas containing a silicon-containing component and hydrogen into a CVD reactor containing at least one filament rod positioned on a device of claim 28, and supplying current by means of the electrode, thereby heating the filament rod by direct current flow to a temperature at which polycrystalline silicon is deposited on the filament rod, and depositing polycrystalline silicon onto the filament rod.

40. A method for producing polycrystalline silicon, comprising introducing a reaction gas containing a silicon-containing component and hydrogen into a CVD reactor containing at least one filament rod positioned on a device of claim 30, and supplying current by means of the electrode, thereby heating the filament rod by direct current flow to a temperature at which polycrystalline silicon is deposited on the filament rod, and depositing polycrystalline silicon onto the filament rod.

41. A method for producing polycrystalline silicon, comprising introducing a reaction gas containing a silicon-containing component and hydrogen into a CVD reactor containing at least one filament rod positioned on a device of claim 33, and supplying current by means of the electrode, thereby heating the filament rod by direct current flow to a temperature at which polycrystalline silicon is deposited on the filament rod, and depositing polycrystalline silicon onto the filament rod.

42. A method for producing polycrystalline silicon, comprising introducing a reaction gas containing a silicon-containing component and hydrogen into a CVD reactor containing at least one filament rod positioned on a device of claim 34, and supplying current by means of the electrode, thereby heating the filament rod by direct current flow to a temperature at which polycrystalline silicon is deposited on the filament rod, and depositing polycrystalline silicon onto the filament rod.

43. A method for producing polycrystalline silicon, comprising introducing a reaction gas containing a silicon-containing component and hydrogen into a CVD reactor containing at least one filament rod positioned on a device of claim 35, and supplying current by means of the electrode, thereby heating the filament rod by direct current flow to a temperature at which polycrystalline silicon is deposited on the filament rod, and depositing polycrystalline silicon onto the filament rod.

44. A method for producing polycrystalline silicon, comprising introducing a reaction gas containing a silicon-containing component and hydrogen into a CVD reactor containing at least one filament rod positioned on a device of claim 36, and supplying current by means of the electrode, thereby heating the filament rod by direct current flow to a temperature at which polycrystalline silicon is deposited on the filament rod, and depositing polycrystalline silicon onto the filament rod.
